(19) United States
(12) Patent Application Publication
(10) Pub. No.: US 2026/0264570 A1
(43) Pub. Date: Sep. 10, 2026

(54) BATTERY SYSTEM

(71) Applicant: TOYOTA JIDOSHA KABUSHIKI KAISHA, Toyota-shi (JP)

(72) Inventor: Yuki MORIYA, Okazaki-shi (JP)

(73) Assignee: TOYOTA JIDOSHA KABUSHIKI KAISHA, Toyota-shi (JP)

(21) Appl. No.: 19/449,735

(22) Filed: Jan. 15, 2026

(30) Foreign Application Priority Data
Mar. 4, 2025 (JP) 2025-033772

(51) Int. Cl. B60L 58/16; B60L 3/00; B60L 3/12; B60L 58/22

(52) U.S. Cl. CPC B60L 58/16; B60L 3/0046; B60L 3/12; B60L 58/22; B60L 2240/547; B60L 2250/16

(57) ABSTRACT

An ECU executes processing including acquiring voltage of all cells when an ignition is turned on and ignition off time is longer than a predetermined amount of time, calculating a voltage variance amount, acquiring traveling distance after updating a display the last time, setting a first threshold value, updating an SOH display when determination is made that the voltage variance amount is greater than the first threshold value, and executing equalization control when the voltage variance amount is greater than a second threshold value.

### CROSS-REFERENCE TO RELATED APPLICATION

This application claims priority to Japanese Patent Application No. 2025-033772 filed on Mar. 4, 2025. The disclosure of the above-identified application, including the specification, drawings, and claims, is incorporated by reference herein in its entirety.

### BACKGROUND

### Technical Field

The present disclosure relates to a battery system.

### Description of Related Art

For example, Japanese Unexamined Patent Application Publication No. 2003-164006 (JP 2003-164006 A) discloses technology in which a degree of battery deterioration is calculated from a voltage value and a current value, a capacity adjustment range is corrected in accordance with the degree of deterioration that is calculated, and the current battery capacity is displayed using segments.

### SUMMARY

In order to learn the current capacity of the battery with high precision, a State Of Charge (SOC) of the battery must change over a certain range or more, but in usage forms in which a user frequently discharges and charges the battery, opportunities for learning the capacity may not be able to be frequently secured, and accordingly display of information regarding full charge capacity may not be updated at an appropriate frequency.

The present disclosure has been made to solve the foregoing problem, and an object thereof is to provide a battery system that updates the display of information regarding the battery capacity at an appropriate frequency.

A battery system according to an aspect of the present disclosure includes a power storage device including a plurality of cells, a display device that displays information regarding a full charge capacity of the power storage device, a detection device that detects voltage of each of the cells, and a control device configured to control the display device. When variance in voltage among the cells is greater than a first threshold value, the control device updates the information regarding the full charge capacity, and displays the information that is updated on the display device.

Thus, when the voltage variance among the cells is greater than the threshold value, the information regarding the full charge capacity is updated, and the information regarding the full charge capacity that is updated at an appropriate frequency can be displayed.

In one embodiment, the battery system is installed in a vehicle. The control device sets the first threshold value to a smaller value the longer a traveling distance after updating last time becomes.

Thus, the threshold value becomes smaller the longer the traveling distance after the updating the last time becomes, and accordingly the information regarding the full charge capacity becomes more likely to be updated. Therefore, the full charge capacity can be displayed updated at an appropriate frequency.

Further, in one embodiment, when the variance is greater than a second threshold value, the control device executes processing to equalize the variance.

Thus, the equalization processing is executed when the variance becomes greater than the second threshold value, thereby enabling decrease in the actual full charge capacity to be suppressed.

According to the present disclosure, a battery system can be provided that updates the display of information regarding the battery capacity at an appropriate frequency.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating an example of an overall configuration of a vehicle equipped with a battery system according to an embodiment;

FIG. 2 is a diagram illustrating an example of a configuration of a battery pack;

FIG. 3 is a diagram showing an example of change in full charge capacity due to voltage variance;

FIG. 4 is a flowchart showing an example of processing executed by an ECU;

FIG. 5 is a diagram showing, in table format, an example of a relation between traveling distance after an SOH display is updated, and a first threshold value; and

FIG. 6 is a diagram illustrating an example of a configuration of a screen displayed on a display device.

### DETAILED DESCRIPTION OF EMBODIMENTS

An embodiment of the present disclosure will be described in detail below with reference to the drawings. Note that the same or corresponding portions are denoted by the same signs throughout the drawings, and description thereof will not be repeated.

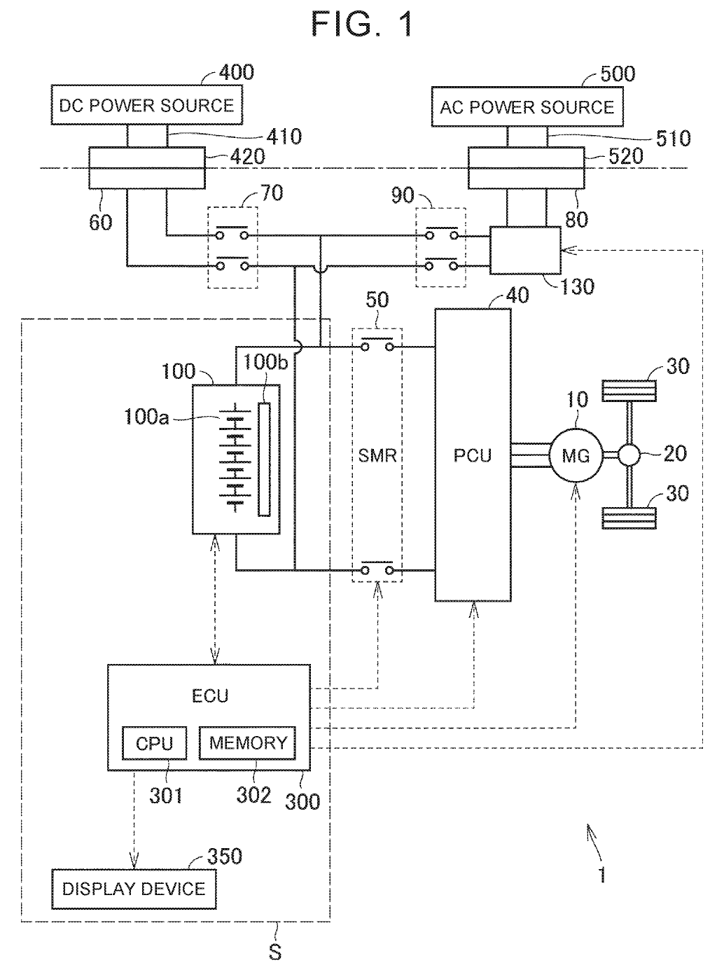

An example of a battery system S according to the present embodiment will be described below. FIG. 1 is a diagram illustrating an example of an overall configuration of a vehicle 1 that is equipped with the battery system S according to the present embodiment. In the present embodiment, the vehicle 1 is an electrified vehicle such as, for example, a battery electric vehicle, a plug-in hybrid electric vehicle, or the like. The vehicle 1 includes a motor generator (MG) 10, which is a rotating electric machine, a power transmission gear 20, drive wheels 30, a power control unit (PCU) 40, a system main relay (SMR) 50, a battery pack 100, an electronic control unit (ECU) 300, which is an example of a control device, and a display device 350. The battery pack 100, the ECU 300, and the display device 350 make up the battery system S.

The MG 10 is, for example, an interior permanent magnet synchronous motor (IPM motor), and has functions of an electric motor and functions of a generator. Output torque of the MG 10 is transmitted to the drive wheels 30 via the power transmission gear 20 that is made up including a reduction gear, a differential, and so forth.

When the vehicle 1 is braked, the MG 10 is driven by the drive wheels 30, and the MG 10 operates as a generator. Thus, the MG 10 also functions as a braking device that performs regenerative braking, by converting kinetic energy of the vehicle 1 into electric power. Regenerative power generated by regenerative braking force of the MG 10 is stored in the battery pack 100.

The PCU 40 is a power conversion device that bidirectionally converts electric power between the MG 10 and the battery pack 100. The PCU 40 includes, for example, an inverter and a converter (neither of which is illustrated) that operate based on control signals from the ECU 300 .

When discharging the battery pack 100, the converter steps up voltage supplied from the battery pack 100 and supplies the stepped up voltage to the inverter. The inverter converts the direct current power supplied from the converter into alternating current power to drive the MG 10.

When charging the battery pack 100, the inverter converts alternating current power generated by the MG 10 into direct current power, and performs supply thereof to the converter. The converter steps down the voltage supplied from the inverter to a voltage suitable for charging the battery pack 100 and performs supply thereof to the battery pack 100 .

The SMR 50 is electrically connected to a power line that connects the battery pack 100 and the PCU 40. When the SMR 50 is closed (ON) in response to a control signal from the ECU 300, electric power can be exchanged between the battery pack 100 and the PCU 40. On the other hand, when SMR 50 is opened (OFF) in response to a control signal from ECU 300, the electrical connection between the battery pack 100 and the PCU 40 is interrupted.

The battery pack 100 includes a battery 100a, which is a power storage device that stores electric power for driving the MG 10, and an equalization circuit (discharge circuit) 100b. The battery 100a is a rechargeable direct current power source (secondary battery) and is configured by stacking a plurality of unit cells (battery cells) and performing electrical connection thereof in series, for example. The unit cell may be, for example, a lithium-ion secondary battery having a liquid or solid electrolyte, a nickel metal hydride secondary battery, or the like. Detailed configurations of the battery 100a and the equalization circuit 100b will be described later.

The vehicle 1 is equipped with a DC inlet 60, and the battery pack 100 can be quickly charged from an external direct current (DC) power source, which is a charging facility. The DC inlet 60 is configured to be connectable with a connector 420 provided at a distal end of a charging cable 410 of an external DC power source (charging facility) 400. A charging relay 70 is electrically connected to a power line connecting the DC inlet 60 and the battery pack 100 . The charging relay 70 switches between supply and interruption of electric power between the DC inlet 60 and the battery pack 100, in accordance with control signals from the ECU 300. When the charging relay 70 is closed, external charging (rapid charging) of the battery pack 100 is executed.

The vehicle 1 is equipped with an AC inlet 80, and the battery pack 100 can be normally charged from an external alternating current (AC) power source that is a charging facility. The AC inlet 80 is configured to be connectable with a connector 520 provided at a distal end of a charging cable 510 of an external AC power source (charging facility) 500. An in-vehicle charger 130 is provided on a power line between the AC inlet 80 and the battery pack 100, and converts alternating current power supplied from the external AC power source into direct current power, and also performs conversion thereof into a voltage that can charge the battery pack 100. A charging relay 90 is electrically connected to a power line connecting the in-vehicle charger 130 and the battery pack 100 . The charging relay 90 switches between supplying and interrupting power between the in-vehicle charger 130 and the battery pack 100, in accordance with control signals from the ECU 300. When the charging relay 90 is closed, external charging (normal charging) of the battery pack 100 is executed.

The ECU 300 includes a central processing unit (CPU) 301 and memory 302 (including, e.g., read-only memory (ROM), random access memory (RAM), and so forth). The ECU 300 controls each piece of equipment such that the vehicle 1 is in a desired state, based on signals from various types of sensors that are omitted from illustration (e.g., throttle valve opening degree signals, vehicle speed signals, and so forth), and information such as maps, programs, and so forth stored in the memory 302.

Also, the ECU 300 executes estimating processing for estimating full charge capacity, and so forth. For example, the ECU 300 calculates an estimated value of the full charge capacity from the amount of change in SOC, which is ΔSOC, calculated from difference between open circuit voltage (OCV) (1) at the start of charging the battery 100a when charging most recently and OCV (2) at the end of charging, and the amount of change in capacity from an integrated value of the charging current from the start to the end of charging.

The display device 350 is configured to display text information as a visual message to the user of the vehicle 1 in response to a control command from the ECU 300 . The display device 350 is made up of, for example, a display unit of a touch panel display provided in the vicinity of the driver's seat. The display unit made up of a liquid crystal display (LCD), an organic electro-luminescence (EL) display, or the like, for example. The display device 350 may be provided, for example, in an instrument cluster (omitted from illustration) that is visible when the user of the vehicle 1 is seated in the driver's seat.

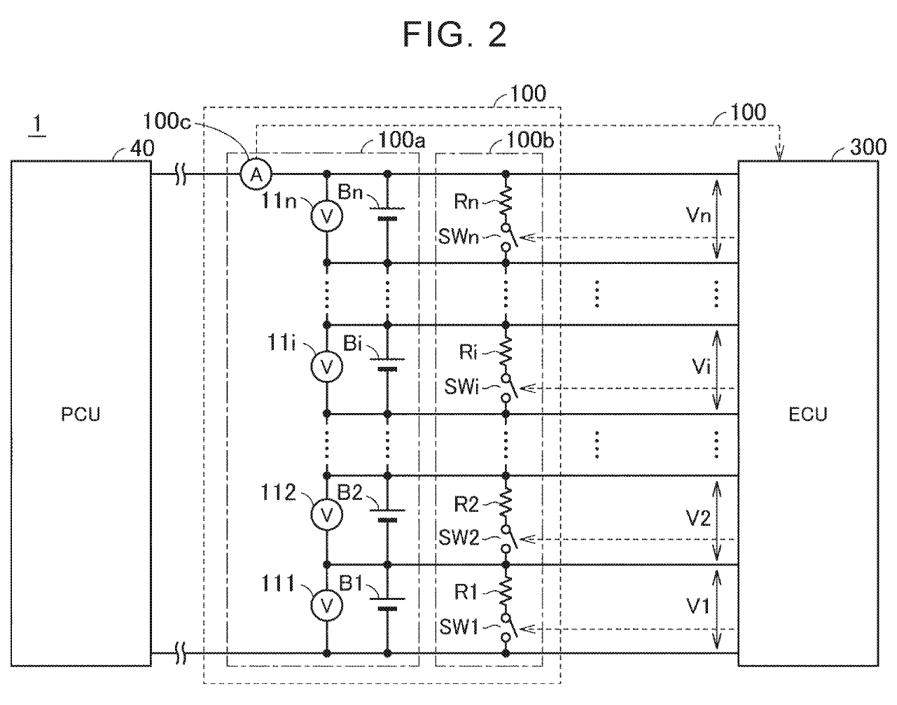

FIG. 2 is a diagram illustrating an example of a configuration of the battery pack 100. The battery 100a includes n cells, B1 to Bn, connected in series. Here, n is a natural number of 2 or more. The battery 100a is provided with a plurality of voltage sensors 111 to 11n that detect voltages V1 to Vn of the corresponding cells, and a current sensor 100c that detects the current flowing through the battery 100a. Each of the sensors outputs a detection result to the ECU 300 .

The equalization circuit 100b includes, for example, n bypass resistors R1 to Rn and n switches SW1 to SWn. The n bypass resistors R1 to Rn are connected in parallel to the n cells B1 to Bn, respectively. The n switches SW1 to SWn are connected in series to the n bypass resistors R1 to Rn, respectively.

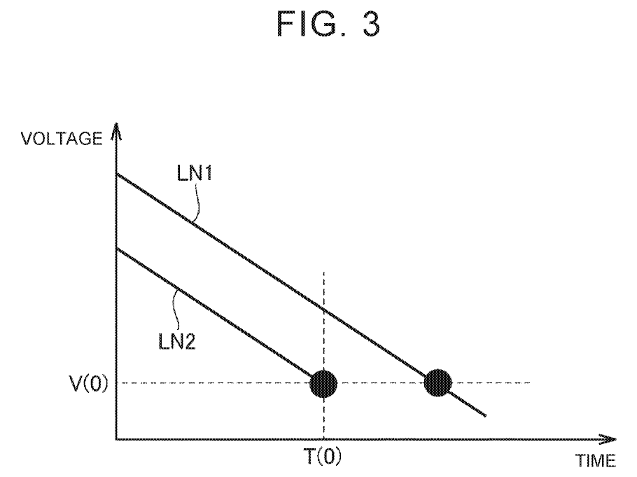

When variance in SOC occurs among the cells in the battery pack 100 having the above-described configuration, there are cases in which voltage variance is occurring. FIG. 3 is a diagram for describing an example of change in full charge capacity due to voltage variance. The vertical axis in FIG. 3 represents voltage. The horizontal axis in FIG. 3 represents time. LN1 in FIG. 3 shows an example of the change over time in voltage of one cell from among cells B1 to Bn, which is a cell in a state of being least deteriorated (hereinafter referred to as cell A). LN2 in FIG. 3 shows an example of the change over time in voltage of one cell from among the cells B1 to Bn other than cell A, which is a cell in a state of being most deteriorated (hereinafter referred to as cell B).

For example, there may be divergence in the full charge capacity between cell A and cell B, due to individual differences in aging deterioration. When cell A is in a state of being less deteriorated than cell B, cell A will be in a state of having a higher voltage than cell B at the same time, as indicated by LN1 and LN2 in FIG. 3, and this relation will continue over time. In a case of such a relation continuing, at a point in time at which the voltage of cell B reaches the lower limit value V(0) at time T(0), the battery 100a is in a state of being unusable, even though cell A has some margin in capacity left. Accordingly, the full charge capacity of the battery 100a is calculated based on the voltage of the cell B.

The ECU 300 executes "equalization control" using the equalization circuit 100b to resolve the above-described voltage variance. More specifically, the ECU 300 extracts a cell with a relatively low voltage from the n cells B1 to Bn as a "reference cell" and controls the equalization circuit 100b to discharge each cell individually such that the voltage of each cell approaches the voltage of the reference cell. This enables resolving unevenness in voltage, i.e., SOC, among the cells B1 to Bn.

In the vehicle 1 having the above configuration, in order to learn the current capacity of the battery 100a with high precision, the SOC of the battery 100a must change over a certain range or more, but in usage forms in which the user frequently discharges and charges the battery, opportunities for learning the capacity may not be able to be frequently secured, and accordingly the display of information regarding full charge capacity may not be updated at an appropriate frequency.

Accordingly, in the present embodiment, when the voltage variance of the cells B1 to Bn is greater than a first threshold value, the ECU 300 updates the information relating to the full charge capacity and displays the updated information. It should be noted that the ECU 300 sets a smaller value for the first threshold value, the longer the traveling distance after updating the display of the information related to the full charge capacity becomes.

Thus, when the voltage variance among the cells is greater than the threshold value, the information regarding the full charge capacity is updated, and the updated information is displayed. In particular, the longer the traveling distance is since updating the last time, the smaller the threshold value becomes, and accordingly the display of the full charge capacity is more likely to be updated. Thus, the display of the full charge capacity can be updated at an appropriate frequency.

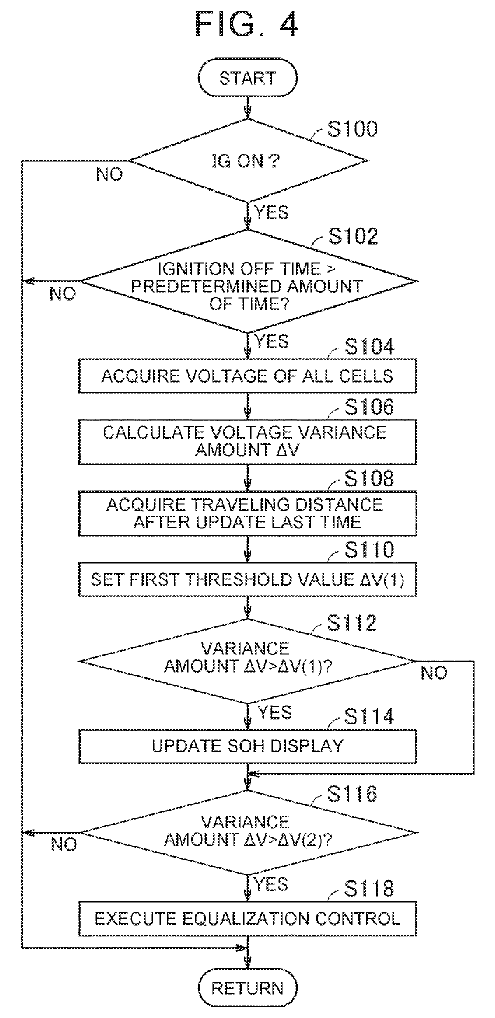

An example of the processing executed by the ECU 300 will be described below with reference to FIG. 4. FIG. 4 is a flowchart showing an example of the processing executed by the ECU 300. The ECU 300 repeatedly executes this process at each control cycle that is set in advance.

In step (hereinafter, "step" will be abbreviated to "S") 100, the ECU 300 determines whether the ignition is turned on. For example, ECU 300 determines whether the ignition has been turned on, based on the state of an ignition flag that is set to an on state when the ignition state changes from an off state to an on state. The ECU 300 may determine that the ignition is on when there is a history of the ignition flag being changed from the off state to the on state within the most recent period set in advance. When determination is made that the ignition is on (YES in S100), the processing transitions to S102.

In S102, the ECU 300 determines whether the ignition off time is longer than a predetermined amount of time. The predetermined amount of time is an amount of time for determining that the state of battery 100a (e.g., temperature, voltage, current) will be in a constant state (unchanging state), and is, for example, an amount of time that is set in advance, adapted through experimentation and so forth. The ECU 300 determines that the ignition off time is longer than the predetermined amount of time when the amount of time over which the ignition flag is in the off state is longer than the predetermined amount of time. When determination is made that the ignition off time is longer than the predetermined amount of time (YES in S102), the processing transitions to S104.

In S104, the ECU 300 acquires voltages V1 to Vn of all of the cells B1 to Bn. The processing then transitions to S106.

In S106, the ECU 300 calculates a voltage variance amount ΔV. Specifically, the ECU 300 calculates a difference obtained by subtracting the smallest value (relatively lowest value) of voltages V1 to Vn from the greatest value (relatively highest value) thereof, as the voltage variance amount ΔV. The processing then transitions to S108.

In S108, the ECU 300 acquires the traveling distance after the update of State Of Health (SOH) display the last time. The SOH is an index indicating the degree of deterioration of the battery 100a, and is expressed as a ratio of the actual full charge capacity of the battery 100a as to the initial full charge capacity of the battery 100a. The closer the SOH is to 0%, the more deteriorated this means that the battery 100a is. The ECU 300 resets the traveling distance to an initial value (e.g., zero) when the SOH display is updated the last time, for example, and thereafter accumulates the traveling distance each time the vehicle is driven in a subsequent driving period, and stores the total in the memory 302 . The ECU 300 acquires the traveling distance stored in the memory 302 as the traveling distance after updating of the SOH display the last time. The processing then transitions to S110.

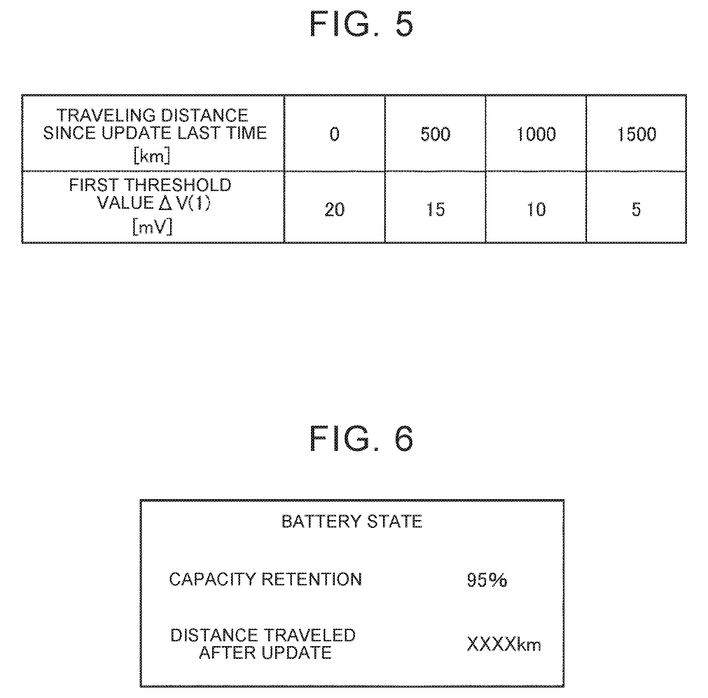

In S110, the ECU 300 sets a first threshold value ΔV(1). The first threshold ΔV(1) is a threshold value of voltage variance for executing updating of the SOH display. The ECU 300 sets first threshold value ΔV(1) using, for example, the travel distance after the updating of the SOH display the last time, and a map that is set in advance. The map that is set in advance may be, for example, a map in a table format, as shown in FIG. 5. FIG. 5 is a diagram showing, in a table format, an example of a relation between traveling distance after an SOH display is updated, and the first threshold value ∆V(1). As shown in FIG. 5, for example, when the travel distance after the update the last time is zero, the first threshold value ΔV(1) is set to 20 mV. The longer the travel distance becomes, the smaller the first threshold value ΔV(1) is set to. For example, when the traveling distance after updating the last time is 500 km, the first threshold value ΔV(1) is set to 15 mV, when the traveling distance after the updating the last time is 1000 km, the first threshold value ΔV(1) is set to 10 mV, and when the traveling distance after updating the last time is 1500 km, the first threshold value ΔV(1) is set to 5 mV.

Note that in FIG. 5, when the distance is less than 500 km, the first threshold value ΔV(1) may be set to 20 mV. When the distance is 500 km or more and less than 1000 km, the first threshold value ΔV(1) may be set to 15 mV. When the distance is 1000 km or more and less than 1500 km, the first threshold value ΔV(1) may be set to 10 mV. When the distance is 1500 km or more, the first threshold value ΔV(1) may be set to 5 mV.

Alternatively, in FIG. 5, the first threshold value ΔV(1) may be set by linear interpolation, using 20 mV and 15 mV, between zero to 500 km. Between 500 km to 1000 km, the first threshold value ΔV(1) may be set by linear interpolation using 15 mV and 10 mV. Between 1000 km to 1500 km, the first threshold value ΔV(1) may be set by linear interpolation using 10 mV and 5 mV. When the distance is 1500 km or more, the first threshold value ΔV(1) may be set to 5 mV. The processing then transitions to S112.

In S112, the ECU 300 determines whether the variance amount ΔV is greater than the first threshold value ΔV(1). When determination is made that a variance amount ΔV(0) is greater than the first threshold value ΔV(1) (YES in S112), the processing transitions to S114.

In S114, the ECU 300 updates the SOH display. The ECU 300 calculates the actual full charge capacity of the battery 100a, and calculates the SOH using the actual full charge capacity that is calculated and the initial full charge capacity. The ECU 300 uses the SOH that is calculated to update information for displaying a display image on the display device 350. FIG. 6 is a diagram illustrating an example of a configuration of a screen displayed on the display device 350. In FIG. 6, text information indicating "battery condition", "capacity retention", and "distance traveled after update", as well as text information indicating the value "95%" corresponding to the "capacity retention" and the value "XXXX km" corresponding to the "distance traveled after update," are displayed in the screen at positions set in advance. The ECU 300 updates the display on the display device 350 using the updated information. The processing then transitions to S116.

In S116, the ECU 300 determines whether the variance amount ΔV is greater than a second threshold value ΔV(2). The second threshold value ΔV(2) is a value that is set in advance, and is adapted through experimentation or the like, for example. The second threshold value ΔV(2) may be, for example, a value that is different from the first threshold value ΔV(1). When determination is made that the variance amount ΔV is greater than the second threshold value ΔV(2) (YES in S116), the processing transitions to S118.

In S118, the ECU 300 executes equalization control. The equalization control is as described above, and accordingly detailed description thereof will not be repeated. This processing then ends. Note that when determination is made that the ignition is in the off state (NO in S100), the ignition off time is the predetermined amount of time or less (NO in S102), or determination is made that the variance amount ΔV is the second threshold value ΔV(2) or lower (NO in S116), this processing ends. Also, when determination is made that the variance amount ΔV is the first threshold value ΔV(1) or lower (NO in S112), the processing transitions to S116.

Operations of the ECU 300 based on the above-described structure and flowchart will now be described. For example, a case will be postulated in which the user performs an operation of turning on the ignition after the vehicle 1 has been in a state in which the ignition is off for a predetermined amount of time or longer.

When the ignition state of the vehicle 1 changes from the ignition-off state to the ignition-on state (YES in S100), determination is made regarding whether the ignition-off time is longer than the predetermined amount of time (S102). When determination is made that the ignition-off time is longer than the predetermined amount of time (YES in S102), the voltages V1 to Vn of all the cells B1 to Bn are acquired (S104). The variance amount ΔV is then calculated by subtracting the smallest value from the greatest value of the voltages V1 to Vn that are acquired (S106). Further, the traveling distance after the updating the SOH display the last time is acquired from the memory 302 of the ECU 300 (S108), and the first threshold value ΔV(1) is set using the traveling distance that is acquired and the map in table format shown in FIG. 5 (S110). When the variance amount ΔV is greater than the first threshold value ΔV(1) that is set (YES in S112), the SOH display is updated (S114). The first threshold value ΔV(1) is set to be lower the longer the traveling distance after the update of the SOH display the last time is, and accordingly the longer the traveling distance is, the more likely it is that the SOH display will be updated. When the variance ΔV is greater than the second threshold value ΔV(2) (YES in S116), the equalization control is executed. Accordingly, the voltage variance (SOC) among the cells B1 to Bn is resolved, and accordingly decrease in the actual full charge capacity is suppressed.

As described above, in the battery system S according to the present embodiment, when the variance amount ΔV of the voltages V1 to Vn of the respective cells B1 to Bn is greater than the first threshold value ΔV(1), the display of information regarding the full charge capacity, such as SOH or the like, is updated. In particular, the longer the traveling distance after the update the last time is, the smaller the first threshold value ΔV(1) becomes, and accordingly the display of the full charge capacity becomes more likely to be updated. Thus, the display of the full charge capacity can be updated at an appropriate frequency. Accordingly, a battery system can be provided that updates the display of information regarding battery capacity at an appropriate frequency.

Further, when the voltage variance of the battery 100a is greater than the second threshold value ΔV(2), the equalization control is executed, and accordingly decrease in the actual full charge capacity can be suppressed.

Modifications will be described below.

In the above embodiment, the SOH indicating the capacity retention was described as an example of information regarding the full charge capacity of the battery 100a to be displayed, but the full charge capacity value itself, for example, may also be displayed as the SOH.

Further, in the above-described embodiment, a case in which the first threshold value ΔV(1) and the second threshold value ΔV(2) are different values has been described as an example, but a case in which the first threshold value ΔV(1) and the second threshold value ΔV(2) are the same value may also be included, depending on the traveling distance after updating the last time.

Note that all or part of the modifications described above may be combined as appropriate.

The embodiments disclosed herein should be considered to be exemplary in all respects and not restrictive. The scope of the present disclosure is set forth in the claims rather than in the above description, and is intended to include all modifications within the meaning and scope equivalent to the claims.

What is claimed is:

1. A battery system comprising:
a power storage device including a plurality of cells;
a display device that displays information regarding a full charge capacity of the power storage device;
a detection device that detects voltage of each of the cells; and
a control device configured to control the display device, wherein, when variance in voltage among the cells is greater than a first threshold value, the control device updates the information regarding the full charge capacity, and displays the information that is updated on the display device.

2. The battery system according to claim 1, wherein:
the battery system is installed in a vehicle; and
the control device sets the first threshold value to a smaller value the longer a traveling distance after updating last time becomes.

3. The battery system according to claim 1, wherein, when the variance is greater than a second threshold value, the control device executes processing to equalize the variance.
